(19) United States
(12) Patent Application Publication
(10) Pub. No.: US 2017/0053822 A1
(43) Pub. Date: Feb. 23, 2017

(54) WARPED WAFERS VACUUM CHUCK

(71) Applicant: CAMTEK LTD., Migdal-Haemek (IL)

(72) Inventors: Arnon Ben Natan, Kiryat Tiv'on (IL); Elik Chen, Naharia (IL)

(21) Appl. No.: 15/230,428

(22) Filed: Aug. 7, 2016

Related U.S. Application Data
(60) Provisional application No. 62/208,719, filed on Aug. 23, 2015.
(60) Provisional application No. 62/210,524, filed on Aug. 27, 2015.

(51) Int. Cl. H01L 21/683

(52) U.S. Cl. CPC H01L 21/6838

(57) ABSTRACT

A chuck that comprises a vacuum system, an upper surface, a groove and a flexible sealing element, wherein at least a bottom portion of the flexible sealing element is positioned within the groove, wherein each one of the groove and the flexible sealing element surrounds a region of the upper surface, wherein the vacuum system is configured to supply vacuum to the region of the upper surface and wherein the flexible sealing element is configured to move between a top position in which an upper portion of the flexible sealing element extends above the upper surface and between a bottom position in which the upper portion of the flexible sealing element does not extend above the upper surface.

### RELATED APPLICATIONS

This application claims priority from U.S. provisional patent Ser. No. 62/208,719 filing date Aug. 23, 2015 and U.S. provisional patent Ser. No. 62/210,524 filing date Aug. 27, 2015, all are being incorporated herein by reference.

### BACKGROUND OF THE INVENTION

Warped Silicon, Polymeric or any other material wafers are often used in the semiconductor industry. Their mechanical distortion might be created due to thermal affect, thermal expansion discrepancies or any other processing mechanical deterioration. Their deformed profile might be concave, convex, “potato chip” (twisted) or randomly distorted. The distorted deflection level might exceed the magnitude of up to 7 mm.

During semiconductor processing the wafers are often being clamped to vacuum chucks in order to flatten them, a fact that enables subsequent inspection, scanning or any other processing subjected to the boundaries of focus depth. Usually, the vacuum chucks are situated onto translation stages that are subjected to dynamic forces during translation.

In general, warped wafers cannot be attached to a standard planar chuck surface by the vacuum attraction due to their deformed profile, hence, vacuum leak is created.

### SUMMARY

According to an embodiment of the invention there may be provided a chuck that may include a vacuum system, an upper surface, a groove and a flexible sealing element; wherein at least a bottom portion of the flexible sealing element may be positioned within the groove; wherein each one of the groove and the flexible sealing element surrounds a region of the upper surface; wherein the vacuum system may be configured to supply vacuum to the region of the upper surface; and wherein the flexible sealing element may be configured to move between a top position in which an upper portion of the flexible sealing element extends above the upper surface and between a bottom position in which the upper portion of the flexible sealing element does not extend above the upper surface.

When (a) a substrate is positioned on the flexible sealing element, (b) vacuum is applied to the region of the upper surface by the vacuum system, and (c) the flexible sealing element extends above the upper surface then a lower surface of the substrate, the flexible sealing element and the upper surface form a sealed environment.

The flexible sealing element may be configured to be lowered, at a first point in time, to an initial position that is below the top position, when a substrate is positioned on the flexible sealing element; wherein when positioned in the initial position the flexible sealing element is positioned above the upper surface.

The flexible sealing element may be configured to be lowered, at a second point in time that follows the first point in time, to another position that is below the initial position, in response to vacuum applied to the region by the vacuum system.

When positioned in the other position the flexible sealing element does not extend above the upper surface; and wherein a lower surface of the substrate and the upper surface form a sealed environment.

The flexible sealing element may be a flexible sealing ring.

The flexible sealing element may not be radially symmetrical about a center of the upper surface.

The flexible sealing element may not be radially symmetrical about a center of the upper surface.

The bottom portion of the flexible sealing element may be a wedge that may be positioned within the groove.

The bottom portion of the flexible sealing element may be thicker by a factor of at least two from the upper portion of flexible sealing element.

The width of the groove may or may not exceed 10 millimeters.

The width of the groove may be about 6.8 millimeters. The term about means a deviation of below 20%.

The upper portion of the flexible sealing element may include a sequence of segments, wherein the segments are oriented to each other when the flexible sealing element is positioned in at least one position.

The upper portion of the flexible sealing element may include multiple segments that are coupled to each other, wherein at least one segment may be linear.

The upper portion of the flexible sealing element may include multiple segments that are coupled to each other, wherein at least one segment may be non-linear.

The flexible sealing element may be formed from three segments that are coupled to each other; wherein the segments are oriented to each other when the flexible sealing element is positioned in at least one position.

The flexible sealing element may be formed from four segments that are coupled to each other; wherein the segments are oriented to each other when the flexible sealing element is positioned in at least one position.

The chuck may include a second groove and a second flexible sealing element; wherein at least a bottom portion of the second flexible sealing element may be positioned within the groove; wherein each one of the second groove and the second flexible sealing element surrounds a second region of the upper surface, the first groove and the first flexible sealing element; wherein the vacuum system may be configured to supply vacuum to the second region of the upper surface; and wherein the second flexible sealing element may be configured to move between a top position in which an upper portion of the second flexible sealing element extends above the upper surface and between a bottom position in which the upper portion of the second flexible sealing element does not extend above the upper surface.

The second flexible sealing element and the first flexible sealing element may be of a same shape but of a different size.

The second flexible sealing element and the first flexible sealing element may differ from each other by shape and size.

The second flexible sealing element and the first flexible sealing element may or may not be coaxial.

The chuck may include a third groove and a third flexible sealing element; wherein at least a bottom portion of the third flexible sealing element may be positioned within the groove; wherein each one of the third groove and the third flexible sealing element surrounds a third region of the upper surface, the second groove and the second flexible sealing element; wherein the vacuum system may be configured to supply vacuum to the third region of the upper surface; and wherein the third flexible sealing element may be configured to move between a top position in which an upper portion of the third flexible sealing element extends above the upper surface and between a bottom position in which the upper portion of the third flexible sealing element does not extend above the upper surface.

According to an embodiment of the invention there may be provided a method for supporting a substrate, the method may include placing the substrate above a region of an upper surface of a chuck so that the substrate contacts a flexible sealing element of the chuck; and supplying vacuum to the region of the upper surface thereby flattening the substrate; wherein at least a bottom portion of the flexible sealing element may be positioned within the groove; wherein each one of the groove and the flexible sealing element surrounds the region of the upper surface; wherein the vacuum system may be configured to supply vacuum to the region of the upper surface; and wherein the flexible sealing element may be configured to move between a top position in which an upper portion of the flexible sealing element extends above the upper surface and between a bottom position in which the upper portion of the flexible sealing element does not extend above the upper surface.

The method may be applied on any chuck that is described in any part of the specification.

### BRIEF DESCRIPTION OF THE INVENTION

The present invention will be understood and appreciated more fully from the following detailed description taken in conjunction with the drawings in which:

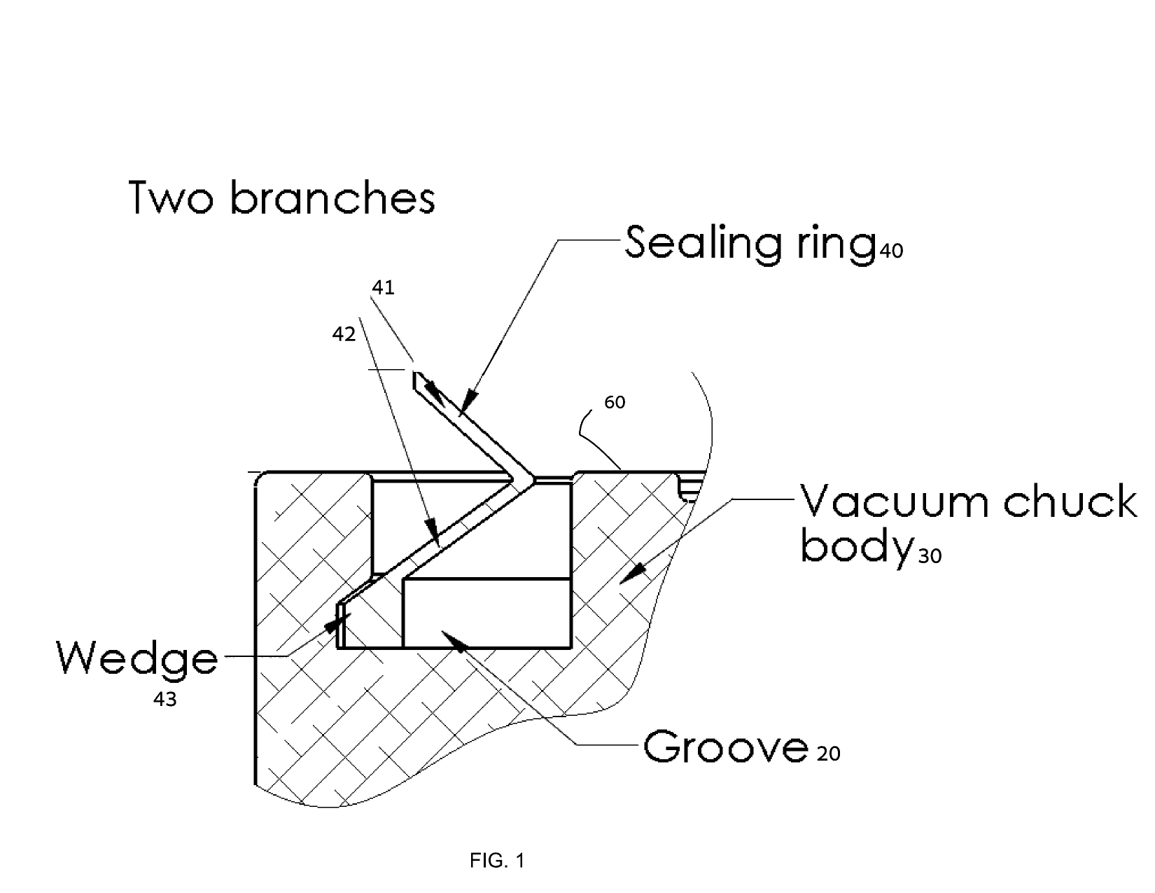

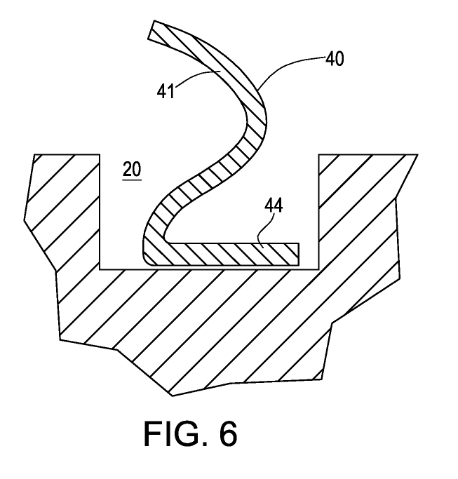

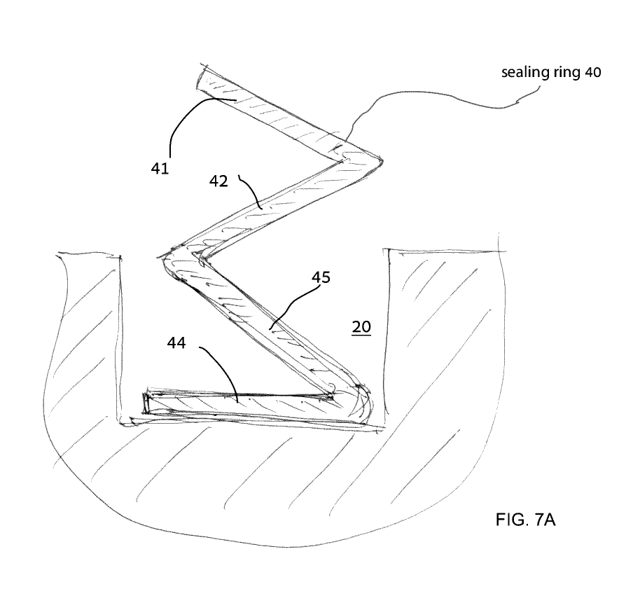

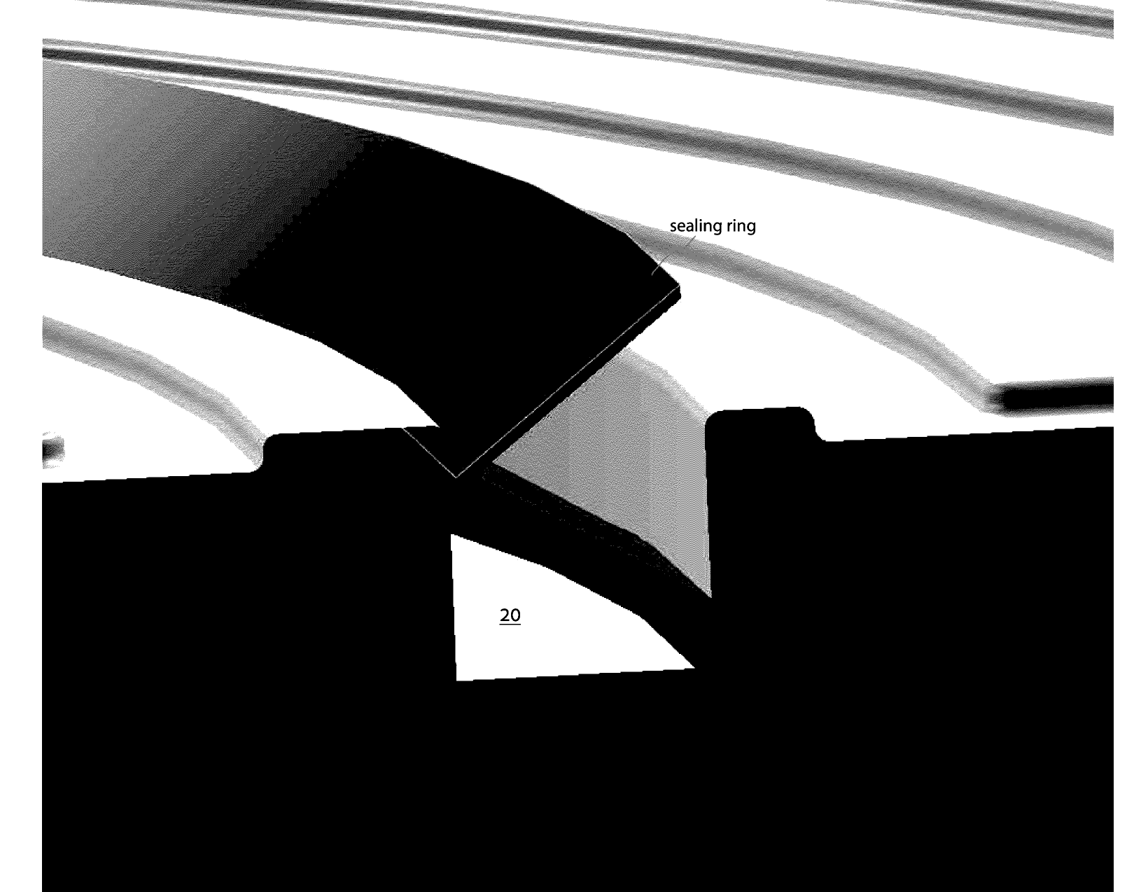

FIGS. 1-6, 7A and 7B illustrate chucks and chuck portions that include sealing rings according to an embodiment of the invention;

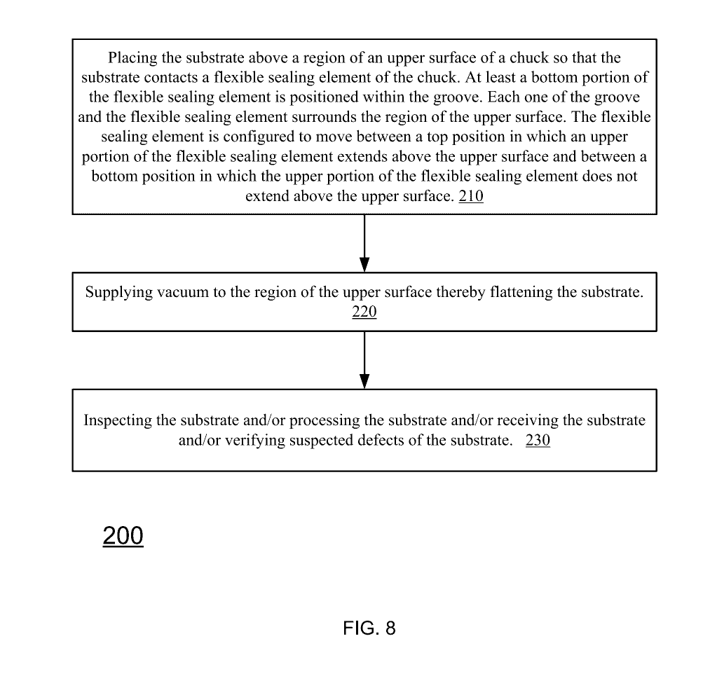

FIG. 8 illustrates a method according to an embodiment of the invention; and

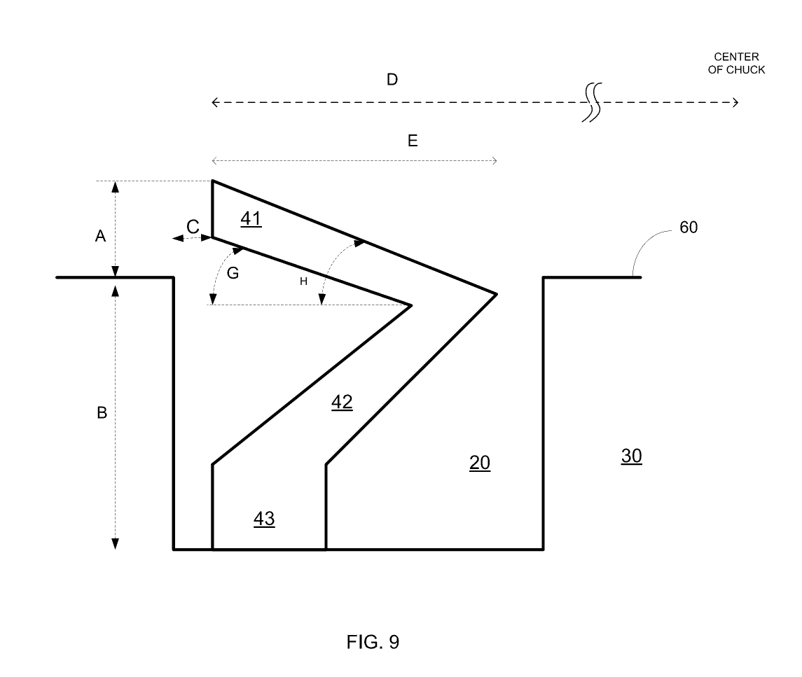

FIG. 9 illustrates a flexible sealing ring and its environment according to an embodiment of the invention.

### DETAILED DESCRIPTION OF THE INVENTION

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

In the following specification, the invention will be described with reference to specific examples of embodiments of the invention. It will, however, be evident that various modifications and changes may be made therein without departing from the broader spirit and scope of the invention as set forth in the appended claims.

The term “sealing ring” is used as a non-limiting of example of a sealing element.

There are provided systems that include flexible sealing rings (sealing rings) at several grooves' locations on top of the chuck surface in order to establish initial vacuum conditions which subsequently enable the vacuum chuck to pull down and flatten the wafer onto its upper surface.

The sealing ring may have a slim profile (height VS. width ratio) which has two major advantages: Minimizes the grooves width, hence, wafer tendency to suck down into the groove by induced vacuum forces is minimized, and its relatively high projection above the chuck surface allows it to handle warped wafers of up to 7 mm deformation.

The sealing ring may be a flexible ring which could accommodate warped wafers, mechanically distorted, by creating an initial vacuum regime, free of leakage, which subsequently enables the vacuum chuck suction to flatten the wafer onto the chuck upper surface. The sealing ring could be made from Silicone rubber, Viton or any other polymeric material which is compatible with the semiconductors processing.

In FIGS. 1-6, 7A and 7B the following elements are associated with the following reference numbers:

### 10 Chuck.

11 Vacuum inlets of chuck body—for receiving vacuum.
20 Groove (may be regarded as a first groove).
30 Vacuum chuck body (also referred to as body).
40 Flexible sealing ring (flexible sealing element)—also referred to as 8″ sealing ring.
41 Top segment (branch) of the flexible sealing ring.
42, 44, 45 Additional segments (branches) of the flexible sealing ring.
43 Wedge of the flexible sealing ring.
50 First vacuum section.
60 Upper surface of the chuck.
70 Vacuum conduit.
81 First region.
82 Second region.
99 Chuck (also referred to as warped chuck)
120 Second groove.
140 Second flexible sealing ring (also referred to as 12″ sealing ring).
150 Second vacuum section.

According to an embodiment of the invention there may be provided a chuck that may include a vacuum system, an upper surface, a groove and a flexible sealing element; wherein at least a bottom portion of the flexible sealing element may be positioned within the groove. Each one of the groove and the flexible sealing element surrounds a region of the upper surface. The vacuum system may be configured to supply vacuum to the region of the upper surface. The flexible sealing element may be configured to move between a top position in which an upper portion of the flexible sealing element extends above the upper surface and between a bottom position in which the upper portion of the flexible sealing element does not extend above the upper surface.

The vacuum system may include vacuum inlets 11, vacuum conduits (not shown) formed within the body 30 of the chuck and are used to feed vacuum to vacuum inlets such as vacuum sections 50 and 150 or to vacuum conduits 70 formed within the upper surface 70.

The upper portion of the flexible sealing element may include the upper segments—such as segments 41 and 42. Segment 44 and/or wedge 43 may belong to a lower portion of the flexible sealing element.

FIG. 1 prescribes a partial cross section of the sealing ring profile located in the chuck designated groove. The sealing ring profile is comprised of 2 flexible branches which, under wafer payload and the initial vacuum regime, are folded downwards and sequensly absolutely confined below the chuck upper surface. For larger stroke the number of branches could be extended. The multiple branches arrangement benefit us with slim sealing profile accompanied by longer travel range. In addition, the sealing ring groove width is relatively narrow (5-8 mm).

The ring is projected 1.5-5 mm above the chuck upper surface, thus enable it to accommodate a variety of warped wafer profile such as: concave, convex, “potato chips”—twisted or any other random distortion. The sealing ring projected wedge at the bottom is confined within the groove recess, a fact that makes it less sensitive to pull out situation. The recess wedge shape could be any other profile such as: rectangular, circular etc.

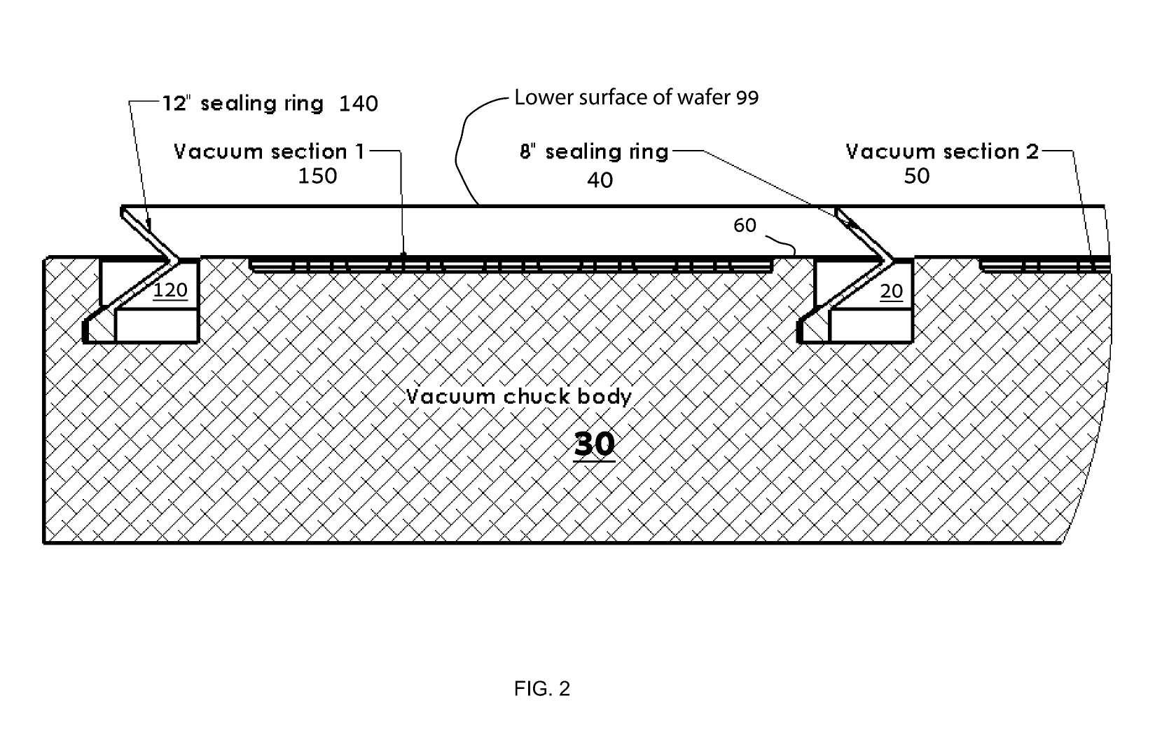

FIG. 2 illustrates chuck arrangement partial cross section which includes two separate vacuum zones (8″ and 12″), in this particular case, accompanied by two sealing rings designated for each vacuum zone. The inner vacuum zone (8″ for example) is being utilized for the 12″ wafer as well and might be activated primarily as the inner diameter zones are usually suffer from smaller deformation magnitudes. In addition, the vacuum trenches are located in-between the sealing rings and maintain the vacuum suction the minute the sealing rings have accomplished their primary function. The vacuum chuck could be machined either with vacuum trenches or embedded with porous media which maintain a uniform vacuum clamping forces across the wafer width.

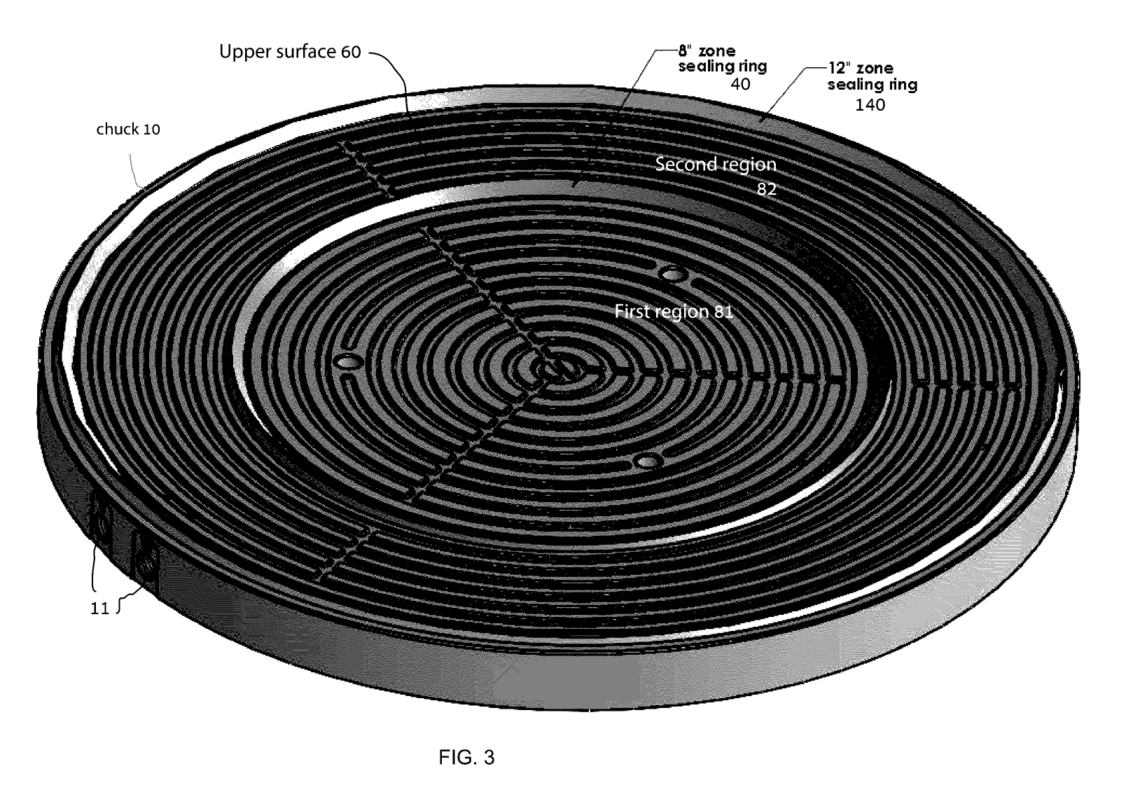

FIG. 3 prescribes the whole chuck structure designated for up to 12″ wafers and includes, in this case, 8″ & 12″ sealing rings only.

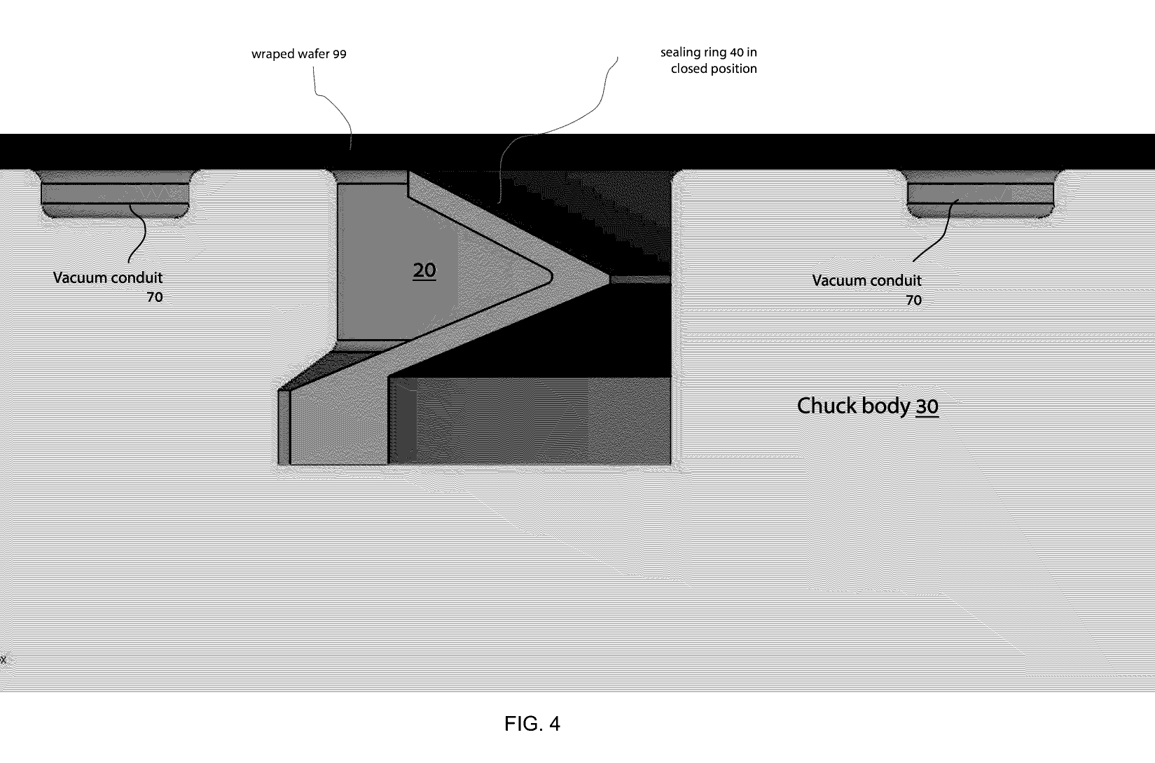

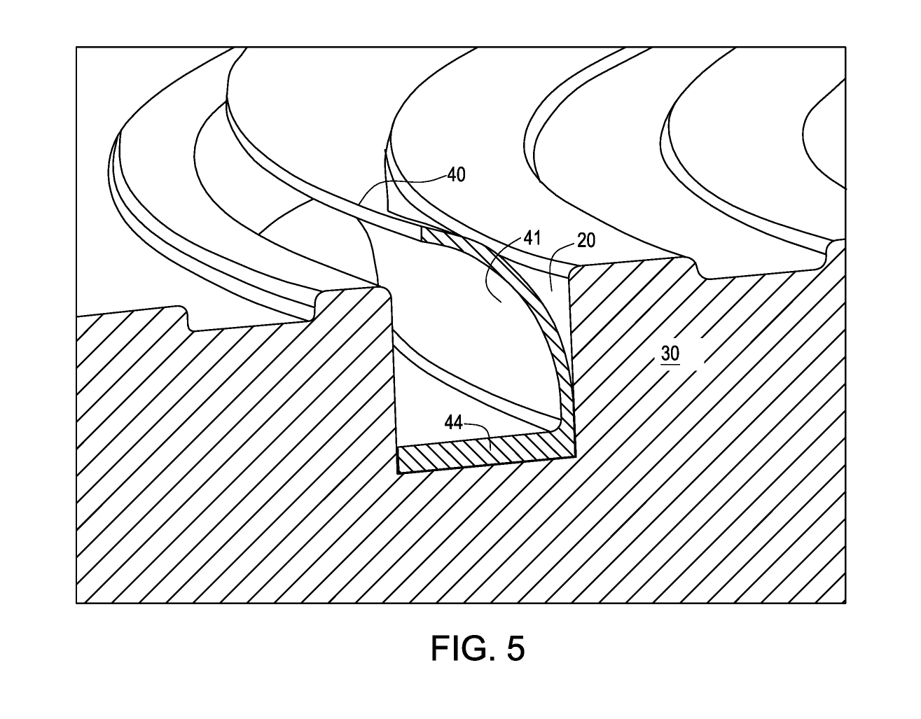

FIG. 4 prescribes the relationship between the wafer, the vacuum chuck and the retractable sealing ring. When the vacuum is activated the sealing ring is folded beneath the chuck surface, inside the groove, and the wafer is being subjected to the chuck surface with the vacuum built up in the trenches.

FIGS. 5, 6, 7A and 7B illustrate various sealing rings of various sizes according to various embodiments of the invention.

The number of sealing rings may differ from two. For single wafer size we could use a single sealing ring or more. The shape, size and dimensions of the sealing rings may differ from those illustrate in the figures.

When a chuck has multiple sealing rings—all the sealing rings may be of the same cross section size and shape. Alternatively, at least one sealing ring may differ from another sealing ring by shape and/or size of cross section.

The chuck may be any type of chuck. The vacuum chuck may be, for example, a circular platform which, on some occasions, is made of solid body engraved with narrow grooves (trenches) machined onto its' upper surface in order to create sufficient induced vacuum attraction force which enable of clamping the wafer to the chuck. Another embodiment is where the chuck body is a solid material and the vacuum suction is created through out a porous media disc which is embedded and/or glued to the chuck upper surface recess in order to create a uniform and continuous suction regime across the wafer area.

The vacuum chuck body or the porous media could be made from steel, stainless steel, ceramic, Aluminum etc.

The vacuum chuck is equipped with vacuum ports and internal or external sealed channels which lead the vacuum flow towards several vacuum zones. As a result, the vacuum chuck is capable to process single or several wafers' diameters starting from 100 mm up to 450 mm which are processed today in the semiconductor field.

The chuck upper surface planarity is usually at the range of few micrometers or even at the sub-micron range in order to minimize the optical inspection/processing system depth of focus sensitivity to wafer surface height variation during processing/inspection.

Instead of failing to properly clamp a wrapped wafer to the chuck due to vacuum leakage (resulting from the wrapped wafer)—the suggested chuck is capable of creating an initial vacuum despite the wrapped wafer. The sealing ring flexibility accommodates with the wafer distorted plain by squeezing under its payload. Then, when the vacuum suction is activated, it creates a close compartment which generates an initial vacuum regime between the chuck and the wafer. Thus subsequently enables the chuck vacuum system to attract the wafer towards the chuck upper surface.

Instead of interfering with processed applied on the wafer—the sealing ring does not interfere with such processes. Due to its profile the sealing ring is absolutely crippled beneath the chuck surface. Its flexibility and profile do not affect wafer planarity due to residual pressing forces.

In order to manage wafer warps that are relatively big (for example—over 7 mm)—using branches that may be folded allows the sealing ring to extend to relatively significant heights (above the upper surface) while being relatively small.

The sealing ring may be positioned within a narrow groove—and this prevents the groove from deforming the wafer.

The sealing ring may be prevented from being pulled out (unintentionally) from the groove by having a lower portion (such as a wedge) that may fit into a recess the is formed in the bottom of the groove. The recess may accommodate with a projected wedge of the sealing ring profile. The wedge is keeping the ring in position.

The chuck may be configured to properly hold and flatten wafers of different sized. This can be done by using multiple spaced apart sealing rings. The vacuum chuck is equipped with a variety of sealing rings of different diameters located at designated vacuum zones which could be activated independently. For example, a severe warped 12″ wafer is primarily clamped by the 8″ vacuum zone/sealing ring and subsequently by the 12″ vacuum zone/sealing ring.

There may be provided a method for placing a wafer on a chuck such as illustrated above. The method may also include inspecting the chuck, applying vacuum, and the like.

FIG. 8 illustrates method 200 according to an embodiment of the invention.

Method 200 may include step 210 of placing the substrate above a region of an upper surface of a chuck so that the substrate contacts a flexible sealing element of the chuck.

At least a bottom portion of the flexible sealing element is positioned within the groove. Each one of the groove and the flexible sealing element surrounds the region of the upper surface. The flexible sealing element is configured to move between a top position in which an upper portion of the flexible sealing element extends above the upper surface and between a bottom position in which the upper portion of the flexible sealing element does not extend above the upper surface.

Step 210 may be followed by step 220 of supplying vacuum to the region of the upper surface thereby flattening the substrate.

Step 220 may be followed by step 230 of inspecting the substrate and/or processing the substrate and/or receiving the substrate and/or verifying suspected defects of the substrate.

FIG. 9 illustrates a flexible sealing ring and its environment according to an embodiment of the invention.

The flexible sealing ring includes top segment 41, intermediate segment 42 and bottom segment.

FIG. 9 illustrates some non-limiting distances and/or angles:

A The height difference between upper surface 60 and the top point of top segment 41. A may equal 4.2 millimeters.
B The depth of groove 20. B may equal 7 millimeters.
C The distance between the leftmost point of top segment 41 and a left sidewall of groove 20. C may equal 1.8 millimeters.
D The distance between the leftmost point of top segment 41 and the center of the chuck. D may equal 196 millimeters.
E The distance between the leftmost point and the right most point of top segment 41. E may equal 7 millimeters.
G The angle between the lower surface of the top segment 41 and the horizon. G may equal 38 degrees.
H The angle between the upper surface of the top segment 41 and the horizon. H may equal 31 degrees.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

However, other modifications, variations, and alternatives are also possible. The specifications and drawings are, accordingly, to be regarded in an illustrative rather than in a restrictive sense.

The word “comprising” does not exclude the presence of other elements or steps then those listed in a claim. It is understood that the terms so used are interchangeable under appropriate circumstances such that the embodiments of the invention described herein are, for example, capable of operation in other orientations than those illustrated or otherwise described herein.

Furthermore, the terms “a” or “an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe.

Thus, these terms are not necessarily intended to indicate temporal or other prioritization of such elements. The mere fact that certain measures are recited in mutually different claims does not indicate that a combination of these measures cannot be used to advantage.

We claim:

1. A chuck that comprises a vacuum system, an upper surface, a groove and a flexible sealing element;
wherein at least a bottom portion of the flexible sealing element is positioned within the groove;
wherein each one of the groove and the flexible sealing element surrounds a region of the upper surface;
wherein the vacuum system is configured to supply vacuum to the region of the upper surface; and
wherein the flexible sealing element is configured to move between a top position in which an upper portion of the flexible sealing element extends above the upper surface and between a bottom position in which the upper portion of the flexible sealing element does not extend above the upper surface.

2. The chuck according to claim 1, wherein when (a) a substrate is positioned on the flexible sealing element, (b) vacuum is applied to the region of the upper surface by the vacuum system, and (c) the flexible sealing element extends above the upper surface then a lower surface of the substrate, the flexible sealing element and the upper surface form a sealed environment.

3. The chuck according to claim 1, wherein the flexible sealing element is configured to be lowered, at a first point in time, to an initial position that is below the top position, when a substrate is positioned on the flexible sealing element; wherein when positioned in the initial position the flexible sealing element is positioned above the upper surface.

4. The chuck according to claim 3, wherein the flexible sealing element is configured to be lowered, at a second point in time that follows the first point in time, to another position that is below the initial position, in response to vacuum applied to the region by the vacuum system.

5. The chuck according to claim 3, wherein when positioned in the other position the flexible sealing element does not extend above the upper surface; and wherein a lower surface of the substrate and the upper surface form a sealed environment.

6. The chuck according to claim 1, wherein the flexible sealing element is a flexible sealing ring.

7. The chuck according to claim 1, wherein the flexible sealing element is not radially symmetrical about a center of the upper surface.

8. The chuck according to claim 1, wherein the flexible sealing element is not radially symmetrical about a center of the upper surface.

9. The chuck according to claim 1, wherein the bottom portion of the flexible sealing element is a wedge that is positioned within the groove.

10. The chuck according to claim 1, wherein the bottom portion of the flexible sealing element is thicker by a factor of at least two from the upper portion of flexible sealing element.

11. The chuck according to claim 1, wherein a width of the groove does not exceed 10 millimeters.

12. The chuck according to claim 1, wherein a width of the groove is about 6.8 millimeters.

13. The chuck according to claim 1, wherein the upper portion of the flexible sealing element comprises a sequence of segments, wherein the segments are oriented to each other when the flexible sealing element is positioned in at least one position.

14. The chuck according to claim 1, wherein the upper portion of the flexible sealing element comprises multiple segments that are coupled to each other, wherein at least one segment is linear.

15. The chuck according to claim 1, wherein the upper portion of the flexible sealing element comprises multiple segments that are coupled to each other, wherein at least one segment is non-linear.

16. The chuck according to claim 1, wherein the flexible sealing element is formed from three segments that are coupled to each other; wherein the segments are oriented to each other when the flexible sealing element is positioned in at least one position.

17. The chuck according to claim 1, wherein the flexible sealing element is formed from four segments that are coupled to each other; wherein the segments are oriented to each other when the flexible sealing element is positioned in at least one position.

18. The chuck according to claim 1, wherein the groove is a first groove, the flexible sealing element is a first flexible sealing element and the region is a first region; wherein the chuck comprises a second groove and a second flexible sealing element;
wherein at least a bottom portion of the second flexible sealing element is positioned within the groove;
wherein each one of the second groove and the second flexible sealing element surrounds a second region of the upper surface, the first groove and the first flexible sealing element;
wherein the vacuum system is configured to supply vacuum to the second region of the upper surface; and
wherein the second flexible sealing element is configured to move between a top position in which an upper portion of the second flexible sealing element extends above the upper surface and between a bottom position in which the upper portion of the second flexible sealing element does not extend above the upper surface.

19. The chuck according to claim 18, wherein the second flexible sealing element and the first flexible sealing element are of a same shape but of a different size.

20. The chuck according to claim 18, wherein the second flexible sealing element and the first flexible sealing element differ from each other by shape and size.

21. The chuck according to claim 18, wherein the second flexible sealing element and the first flexible sealing element are coaxial.

22. The chuck according to claim 18, wherein the second flexible sealing element and the first flexible sealing element are not coaxial.

23. The chuck according to claim 18, comprises a third groove and a third flexible sealing element;
wherein at least a bottom portion of the third flexible sealing element is positioned within the groove;
wherein each one of the third groove and the third flexible sealing element surrounds a third region of the upper surface, the second groove and the second flexible sealing element;
wherein the vacuum system is configured to supply vacuum to the third region of the upper surface; and
wherein the third flexible sealing element is configured to move between a top position in which an upper portion of the third flexible sealing element extends above the upper surface and between a bottom position in which the upper portion of the third flexible sealing element does not extend above the upper surface.

24. A method for supporting a substrate, the method comprises:
placing the substrate above a region of an upper surface of a chuck so that the substrate contacts a flexible sealing element of the chuck; and
supplying vacuum, by a vacuum system, to the region of the upper surface thereby flattening the substrate;
wherein at least a bottom portion of the flexible sealing element is positioned within the groove;
wherein each one of the groove and the flexible sealing element surrounds the region of the upper surface; and
wherein the flexible sealing element is configured to move between a top position in which an upper portion of the flexible sealing element extends above the upper surface and between a bottom position in which the upper portion of the flexible sealing element does not extend above the upper surface.
